(19) United States
(12) Patent Application Publication
(10) Pub. No.: US 2022/0085785 A1
(43) Pub. Date: Mar. 17, 2022

(54) CRYSTAL RESONATOR, AND INTEGRATED STRUCTURE OF CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Zhejiang (CN)

(21) Appl. No.: 17/419,529

(22) PCT Filed: Nov. 5, 2019
(86) PCT No.: PCT/CN2019/115650

§ 371 Date: Jun. 29, 2021

(30) Foreign Application Priority Data
Dec. 29, 2018 (CN) 201811643124.6

(51) Int. Cl. H03H 3/02; H03H 9/05

(52) U.S. Cl. CPC H03H 3/02; H03H 9/0538

(57) ABSTRACT

A structure and method for integrating a crystal resonator with a control circuit are disclosed. The integration of the crystal resonator with the control circuit is accomplished by bonding a substrate (300) containing an upper cavity (310) to a device wafer containing both the control circuit and a lower cavity (120) so that a piezoelectric vibrator is sandwiched between the device wafer (100) and the substrate (300). In addition, a semiconductor die (700) may be bonded to a back side of the device wafer (100).

### TECHNICAL FIELD

The present invention relates to the field of semiconductor technology and, in particular, to a structure and method for integrating a crystal resonator with a control circuit.

### BACKGROUND

A crystal resonator is a device operating on the basis of inverse piezoelectricity of a piezoelectric crystal. As key components of crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, existing crystal resonators are not only hard to be integrated with other semiconductor components and bulky themselves.

For example, common existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated integrated circuit by soldering or gluing additionally hinders the crystal resonators' miniaturization.

### SUMMARY OF THE INVENTION

It is an objective of the present invention to provide a method for integrating a crystal resonator with a control circuit, which overcomes the above described problems with conventional crystal resonators, i.e., a bulky size and difficult integration.

According to the present invention, the above object is attained by a method for integrating a crystal resonator with a control circuit, including:

providing a device wafer having the control circuit formed therein;

forming a lower cavity of the crystal resonator in the device wafer by etching the device wafer from a front side thereof;

providing a substrate and etching the substrate so that an upper cavity of the crystal resonator is formed therein, wherein the upper cavity is formed in opposition to the lower cavity;

forming a piezoelectric vibrator including a top electrode, a piezoelectric crystal and a bottom electrode, which are formed either on the front side of the device wafer or on the substrate;

forming a first connecting structure on the device wafer or on the substrate;

bonding the substrate to the front side of the device wafer such that the piezoelectric vibrator is situated between the device wafer and the substrate, with the upper and lower cavities being located on two sides of the piezoelectric vibrator, and with the first connecting structure electrically connecting both the top and bottom electrodes of the piezoelectric vibrator to the control circuit; and

bonding a semiconductor die to a back side of the device wafer and forming a second connecting structure electrically connecting the semiconductor die to the control circuit.

It is another objective of the present invention to provide a structure for integrating a crystal resonator with a control circuit, including:

a device wafer in which the control circuit and a lower cavity are formed, the lower cavity exposed from a front side of the device wafer;

a substrate, which is bonded to the device wafer from the front side thereof, and in which an upper cavity is formed, the upper cavity having an opening arranged in opposition to an opening of the lower cavity;

a piezoelectric vibrator including a top electrode, a piezoelectric crystal and a bottom electrode, the piezoelectric vibrator arranged between the device wafer and the substrate so that the lower and upper cavities are on opposing sides of the piezoelectric vibrator;

a first connecting structure configured to electrically connect the top and bottom electrodes of the piezoelectric vibrator to the control circuit;

a semiconductor die bonded to a back side of the device wafer; and

a second connecting structure configured to electrically connect the semiconductor die to the control circuit.

In the provided method, planar fabrication processes are utilized to form the lower and upper cavities in the device wafer and substrate, respectively, and the substrate is bonded to the device wafer in such a manner that the piezoelectric vibrator is sandwiched between the device wafer and substrate. In this way, the control circuit and crystal resonator are integrated on the same device wafer. Additionally, the semiconductor die can be further bonded to the back side of the device wafer, resulting in an enhancement in performance of the crystal resonator by allowing on-chip modulation of its parameters (e.g., in order to correct raw deviations of the crystal resonator such as temperature and frequency drifts), in addition to a significant increase in the crystal resonator's degree of integration.

Therefore, compared with traditional crystal resonators (e.g., surface-mount ones), in addition to being able to integrate with other semiconductor components with a higher degree of integration, the crystal resonator of the present invention is more compact, miniaturized in size, less costly and less power-consuming.

### BRIEF DESCRIPTION OF THE DRAWINGS

FIG. 1 shows a flowchart schematically illustrating a method for integrating a crystal resonator with a control circuit according to a first embodiment of the present invention.

FIGS. 2a to 2i are schematic representations of structures resulting from steps in the method according to the first embodiment of the present invention.

FIGS. 3a to 3d are schematic representations of structures resulting from steps in a method for integrating a crystal resonator with a control circuit according to a third embodiment of the present invention.

In these figures,

100—device wafer; AA—device area; 100U—front side; 100D—back side; 100A—substrate wafer; 100B—dielectric layer; 110—control circuit; 111—first circuit; 111a—first interconnect; 111b—third interconnect; 112—second circuit; 112a—second interconnect; 112b—fourth interconnect; 120—lower cavity; 211b—first conductive plug; 212b—second conductive plug; 221b—first connecting wire; 222b—second connecting wire; 230—third conductive plug; 410—first plastic encapsulation layer; 420—second plastic encapsulation layer; 500—piezoelectric vibrator; 510—bottom electrode; 520—piezoelectric crystal; 530—top electrode; 610—rewiring layer; 700—semiconductor die.

### DETAILED DESCRIPTION

The core idea of the present invention is to provide a structure and method for integrating a crystal resonator with a control circuit, in which planar fabrication processes are utilized to integrate the crystal resonator and an associated semiconductor die both on a device wafer where the control circuit is formed. This, on the one hand, results in a size reduction of the crystal resonator and, on the other hand, allows an increased degree of integration of the crystal resonator with other semiconductor components.

Specific embodiments of the proposed structure and method will be described below in greater detail with reference to the accompanying drawings. Features and advantages of the invention will be more apparent from the following description. Note that the accompanying drawings are provided in a very simplified form not necessarily drawn to exact scale and for the only purpose of helping to explain the disclosed embodiments in a more convenient and clearer way.

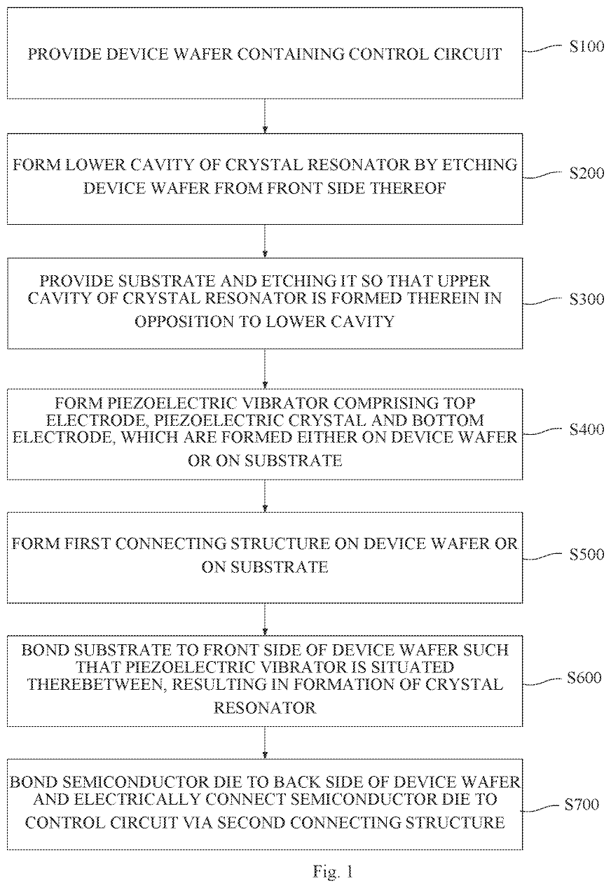

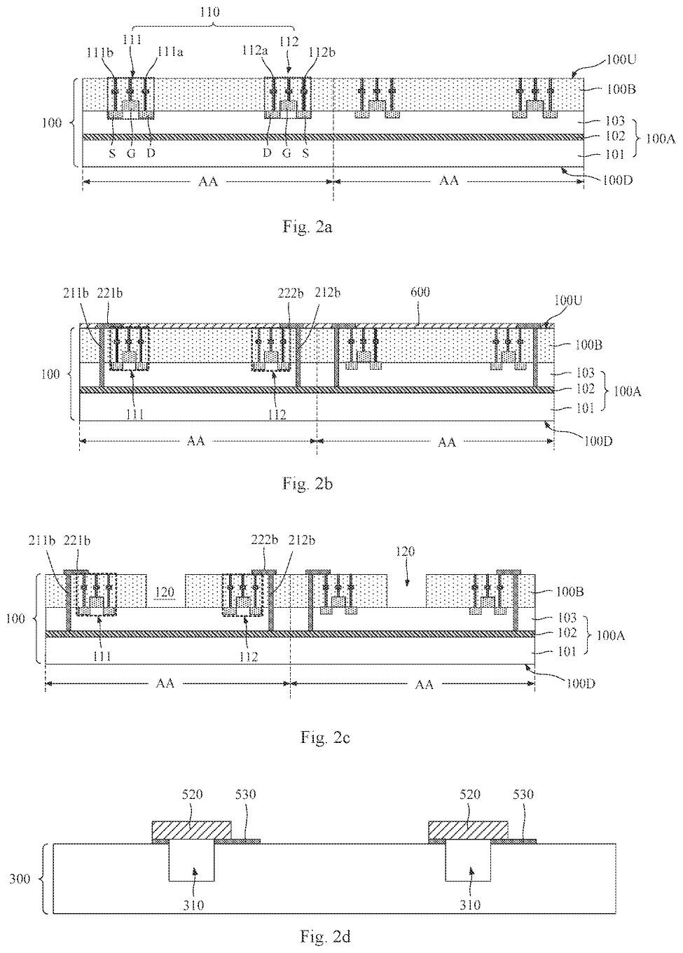

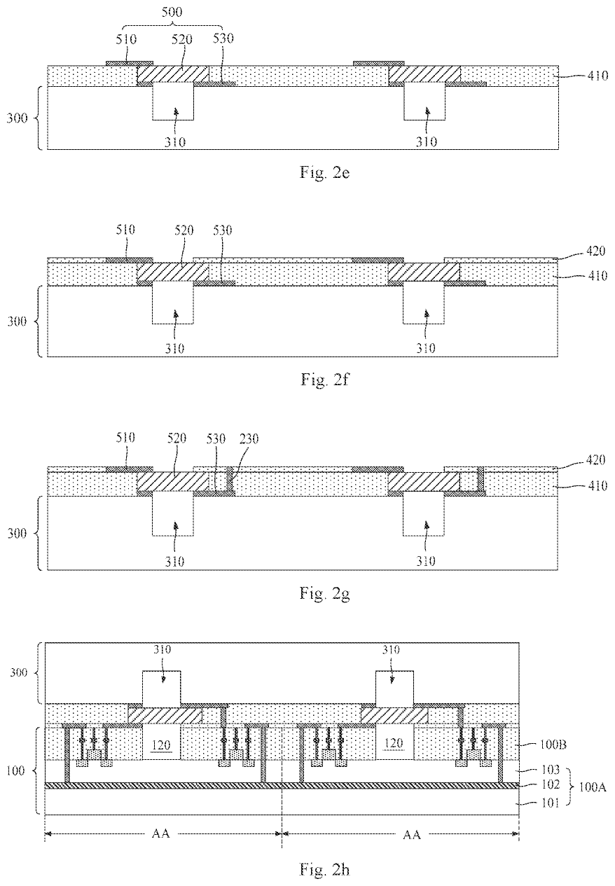

FIG. 1 shows a flowchart schematically illustrating a method for integrating a crystal resonator with a control circuit according to an embodiment of the present invention, and FIGS. 2a to 2i are schematic representations of structures resulting from steps in the method for integrating a crystal resonator with a control circuit according to an embodiment of the present invention. In the following, steps for forming the crystal resonator will be described in detail with reference to the figures.

In step S100, with reference to FIG. 2a, a device wafer 100 is provided, and a control circuit 110 is formed in the device wafer 100.

Specifically, the device wafer 100 has a front side 100U and a back side 100D opposite to the front side, and the control circuit 110 includes a plurality of interconnects, at least some of which extend to the front side of the device wafer. The control circuit 110 may be adapted to, for example, apply an electrical signal to a subsequently formed piezoelectric vibrator.

A plurality of crystal resonators may be formed on the single device wafer 100. Accordingly, there may be a plurality of device areas AA defined on the device wafer 100, with the control circuit 110 being formed in one of the device areas AA.

The control circuit 110 may include a first circuit 111 and a second circuit 112, the first circuit 111 and the second circuit 112 may be electrically connected to a top electrode and a bottom electrode of the subsequently formed piezoelectric vibrator, respectively.

With continued reference to FIG. 2a, the first circuit 111 may include a first transistor, a first interconnect 111a and a third interconnect 111b. The first transistor may be buried within the device wafer 100, and the first and third interconnect 111a, 111b may be both connected to the first transistor and extend to the front side of the device wafer 100. For example, the first interconnect 111a may be connected to a drain of the first transistor, and the third interconnect 111b to a source of the first transistor.

Similarly, the second circuit 112 may include a second transistor, a second interconnect 112a and a fourth interconnect 112b. The second transistor may be buried within the device wafer 100, and the second and fourth interconnects 112a, 112b may be both connected to the second transistor and extend to the front side of the device wafer 100. For example, the second interconnect 112a may be connected to a drain of the second transistor, and the fourth interconnect 112b may be connected to a source of the second transistor.

In this embodiment, the device wafer 100 includes a substrate wafer 100A and a dielectric layer 100B on the substrate wafer 100A. Additionally, the first and second transistors may be both formed on the substrate wafer 100A and covered by the dielectric layer 100B. The third, first, second and fourth interconnects 111b, 111a, 112a, 112b may be all formed within the dielectric layer 100B and extend to a surface of the dielectric layer 100B facing away from the substrate wafer.

The substrate wafer 100A may be either a silicon wafer or a silicon-on-insulator (SOI) wafer. In the case of the substrate wafer 100A being an SOI wafer, the substrate wafer may specifically include a base layer 101, a buried oxide layer 102 and a top silicon layer 103 stacked in sequence from the back side 100D to the front side 100U.

It is to be noted that, in this embodiment, the interconnects of the control circuit 110 extend to the front side 100U of the device wafer, while the subsequently formed piezoelectric vibrator is located on the back side 100D of the device wafer. Accordingly, a second connecting structure may be formed in a subsequent process for leading signal ports of the control circuit 110 from the front side of the device wafer to back side of the device wafer and electrically connecting them to a subsequently formed semiconductor die.

Specifically, the second connecting structure may include conductive plugs and connecting wires. The conductive plugs may extend through the device wafer 100, and the connecting wires may be formed on the front side of the device wafer 100 and connect the conductive plugs to the control circuit. As such, the conductive plugs and connecting wires in the second connecting structure can be used to lead connection ports of the control circuit, to which the semiconductor die is to be connected, from the front to back side of the device wafer.

In this embodiment, the conductive plugs in the second connecting structure include a first conductive plug 211b and a second conductive plug 212b, and the connecting wires in the second connecting structure include a first connecting wire 221b and a second connecting wire 222b. The conductive plugs and connecting wires in the second connecting structure may be formed using a method including, for example, the following steps:

Step 1: Etch the device wafer from the front side 100U of the device wafer so that connecting holes are formed therein. In this embodiment, a first connecting hole and a second connecting hole are formed. Specifically, bottoms of both the first and second connecting holes may be closer to the back side 100D of the device wafer than to a bottom of the control circuit.

Step 2: With reference to FIG. 2b, fill a conductive material into the connecting holes, thereby resulting in the formation of the conductive plugs. In this embodiment, a conductive material is filled in the first and second connecting holes to result in the formation of the first and second conductive plugs 211b, 212b.

In this embodiment, bottoms of the first and second conductive plugs 211b, 212b are closer to the back side 100D of the device wafer than to the control circuit. Specifically, the first and second transistors 111T, 112T may be formed within the top silicon layer 103 above the buried oxide layer 102, while the first and second conductive plugs 211b, 212b may penetrate sequentially through the dielectric layer 100B and the top silicon layer 103 and terminate at the buried oxide layer 102. Thus, it will be recognized that the buried oxide layer 102 may serve as an etch stop layer for the etching process for forming the connecting holes. In this way, high etching accuracy can be achieved for the etching process.

Step 3: With continued reference to FIG. 2b, form the connecting wires on the front side of the device wafer 100. In this embodiment, the first connecting wire 221b and the second connecting wire 222b are formed with the first connecting wire 221b connecting the first conductive plug 211b to the third interconnect 111b and the second connecting wire 222b connecting the second conductive plug 212b to the fourth interconnect 112b.

The device wafer may be subsequently thinned from the back side so that the first and second conductive plugs 211b, 212b are exposed at the processed back side and brought into electrical connection with the semiconductor die.

It is to be noted that although the first and second conductive plugs 211b, 212b have been described above as being formed from the front side of the device wafer prior to the formation of the first and second connecting wires 221b, 222b, the first and second conductive plugs 211b, 212b may be alternatively formed from the back side of the device wafer subsequent to the thinning of the device wafer, as described in greater detail below.

In step S200, with reference to FIG. 2c, a lower cavity 120 of the crystal resonator is formed by etching the device wafer 100 from the front side thereof. Specifically, the lower cavity 120 may be exposed at the front side 100U of the device wafer and may be configured to provide a space in which the subsequently formed piezoelectric vibrator can vibrate.

In this embodiment, the lower cavity 120 is formed in the dielectric layer 100B of the device wafer. In each device area AA, such a lower cavity 120 may be formed. A method for forming the lower cavity 120 may include etching the dielectric layer 100B until the substrate wafer 100A is reached. In this manner, the lower cavity 120 may be formed in the dielectric layer 100B. The lower cavity 120 may have a depth that is determined, without limitation, as practically required. For example, the lower cavity 120 may either extend only in the dielectric layer 100B or further into the substrate wafer 100A from the dielectric layer 100B.

It is to be noted that the relative positions of the lower cavity 120 and the first and second circuits shown in the figures are merely for illustration, and in practice, the arrangement of the first and second circuits may depend on the actual circuit layout requirements. The present invention is not limited in this regard.

As noted above, the substrate wafer 100A may be implemented as an SOI wafer. In this case, the etching process for forming the lower cavity may proceed further through a top silicon layer of the SOI wafer so that the formed lower cavity extends from the dielectric layer down to an underlying buried oxide layer of the wafer.

In step S300, with reference to FIG. 2d, a substrate 300 is provided and etched so that an upper cavity 310 of the crystal resonator is formed therein in opposition to the lower cavity 120 in position. Likewise, the upper cavity 310 may have a depth that is determined, without limitation, as practically required. In a subsequent process for bonding the substrate 300 to the device wafer 100, the upper and lower cavities 310, 120 may be positioned on opposing sides of the piezoelectric vibrator.

On the substrate 300, there may be also defined a plurality of device areas AA corresponding to those of the device wafer 100, and the lower cavity 120 may be formed in one of the device areas AA on the device wafer 100.

In step S400, a piezoelectric vibrator including a top electrode, a piezoelectric crystal and a bottom electrode is formed. Each of the top electrode, the piezoelectric crystal and the bottom electrode may be formed on one of the front side of the device wafer 100 and the substrate 300.

In other words, it is possible that the top electrode, the piezoelectric crystal and the bottom electrode in the piezoelectric vibrator are all formed on the front side of the device wafer 100, or on the substrate 300. It is also possible that the bottom electrode of the piezoelectric vibrator is formed on the front side of the device wafer 100, with the top electrode and piezoelectric crystal of the piezoelectric vibrator being formed as a stack on the substrate 300. It is still possible that the bottom electrode and the piezoelectric crystal of the piezoelectric vibrator are formed as a stack on the front side of the device wafer 100, with the top electrode of the piezoelectric vibrator being formed on the substrate 300.

In this embodiment, the top electrode, piezoelectric crystal and bottom electrode in the piezoelectric vibrator are all formed on the substrate 300. Specifically, a method for forming the piezoelectric vibrator on the substrate 300 may include the following steps:

Step 1: With reference to FIG. 2d, form the top electrode 530 at a predetermined location on a surface of the substrate 300. In this embodiment, the top electrode 530 is positioned around the upper cavity 310. In a subsequent process, the top electrode 530 may be electrically connected to the control circuit 110, more exactly, the top electrode 530 may be electrically connected to the second interconnect in the second circuit 112.

Step 2: With continued reference to FIG. 2d, bond the piezoelectric crystal 520 to the top electrode 530. In this embodiment, the piezoelectric crystal 520 is arranged above the upper cavity 310, with the peripheral edge portions of the piezoelectric crystal 520 residing on the top electrode 530. The piezoelectric crystal 520 may be, for example, a quartz crystal plate.

In this embodiment, the upper cavity 310 is narrower than the piezoelectric crystal 520 so that the piezoelectric crystal 520 can be arranged with its peripheral edge portions residing on the surface of the substrate, thus covering an opening of the upper cavity 310.

However, in other embodiments, the upper cavity may be made up of, for example, a first portion and a second portion. The first portion may be deeper in the substrate than the second portion, and the second portion may be adjacent to the surface of the substrate. Additionally, the first portion may be narrower than the piezoelectric crystal 520, and the second portion may be broader than the piezoelectric crystal. In this way, the piezoelectric crystal 520 may be at least partially received in the second portion, with its peripheral edge portions residing on top edges of the first portion. In addition, it is devisable that the opening of the upper cavity is wider than the piezoelectric crystal.

Further, the top electrode 530 may have an extension laterally extending beyond the piezoelectric crystal 520 thereunder. In a subsequent process, the top electrode 530 may be connected to the second interconnect in the second circuit 112 via the extension.

Step 3: With reference to FIG. 2e, form the bottom electrode 510 on the piezoelectric crystal 520. The bottom electrode 510 may be so formed that a central portion of the piezoelectric crystal 520 is exposed therefrom. In a subsequent process, the bottom electrode 510 may be electrically connected to the control circuit 110, more exactly, the bottom electrode 510 may be electrically connected to the first interconnect in the first circuit 111.

Thus, in the control circuit 110, the first circuit 111 may be electrically connected to the bottom electrode 510, and the second circuit 112 to the top electrode 530. As such, an electrical signal can be applied to the bottom and top electrodes 510, 530 to create an electric field between the bottom and top electrodes 510, 530, which causes the piezoelectric crystal 520 between the top and bottom electrodes 530, 510 to change its shape. The magnitude of the shape change of the piezoelectric crystal 520 depends on the strength of the electric field, and when the electric field between the top and bottom electrodes 530, 510 is inverted, the piezoelectric crystal 520 will change its shape in the opposite direction. Therefore, when the control circuit 110 applies an AC signal to the top and bottom electrodes 530, 510, the piezoelectric crystal 520 will change shape alternately in opposite directions and thus alternately contract and expand due to oscillations of the electric field. As a result, the piezoelectric crystal 520 will vibrate mechanically.

In this embodiment, a method for forming the bottom electrode 510 on the substrate 300 may include the steps detailed below.

In a first step, with reference to FIG. 2e, a first plastic encapsulation layer 410 is formed on the substrate 300, the first plastic encapsulation layer 410 covers the substrate 300, and from which the piezoelectric crystal 520 is exposed. It is to be noted that, in this embodiment, since the top electrode 530 is formed under the piezoelectric crystal 520, with the extension thereof extending laterally beyond the piezoelectric crystal 520, the first plastic encapsulation layer 410 also covers the extension of the top electrode 530.

In addition, a top surface of the first plastic encapsulation layer 410 may not be higher than that of the piezoelectric crystal 520. In this embodiment, the formation of the first plastic encapsulation layer 410 may involve planarizing the first plastic encapsulation layer 410 so that its top surface is flush with that of the piezoelectric crystal 520.

In a second step, with continued reference to FIG. 2e, the bottom electrode 510 is formed on the surface of the piezoelectric crystal 520. The bottom electrode 510 has an extension extending laterally beyond the piezoelectric crystal 520 over the first plastic encapsulation layer 410. In a subsequent process, the bottom electrode 510 may be connected to the control circuit (more exactly, to the first interconnect in the first circuit 111) via the extension.

The bottom and top electrodes 510, 530 may be formed from a material including silver. The bottom and top electrodes 510, 530 may be successively formed using a thin-film deposition process or a vapor deposition process.

It is to be noted that, in this embodiment, the top electrode 530, the piezoelectric crystal 520 and the bottom electrode 510 are successively formed over the substrate 300 using semiconductor processes. However, in other embodiments, it is also possible to form the top and bottom electrodes on opposing sides of the piezoelectric crystal and then bond the three as a whole onto the substrate.

Optionally, subsequent to the formation of the bottom electrode 510, the method may further include forming a second plastic encapsulation layer on the first plastic encapsulation layer 410, which provides the substrate 300 with a fatter surface favorable to the subsequent bonding process.

With reference to FIG. 2f, the second plastic encapsulation layer 420 is formed on the first plastic encapsulation layer 410, the second plastic encapsulation layer 420 may have a top surface not higher than that of the bottom electrode 510 so that the bottom electrode 510 remains exposed. In this embodiment, the formation of the second plastic encapsulation layer 420 may involve planarizing the second plastic encapsulation layer 420 so that its top surface is flush with that of the bottom electrode 510. Moreover, the central portion of the piezoelectric crystal 520 may also be exposed from the second plastic encapsulation layer 420. In this way, when the substrate 300 is subsequently bonded to the device wafer 100, the central portion of the piezoelectric crystal 520 can interface with the lower cavity 120 in the device wafer 100.

In step S500, a first connecting structure is formed on the device wafer 100 or on the substrate 300. The first connecting structure may be configured for electrical connection of the bottom electrode 510 on the substrate 300 to the control circuit on the device wafer 100 (more exactly, to the first interconnect in the first circuit) and of the top electrode 530 on the substrate 300 to the control circuit on the device wafer 100 (more exactly, to the second interconnect in the second circuit).

Specifically, the first connecting structure may include a first connection and a second connection, the first connection connects the first interconnect 111a to the bottom electrode 510 of the piezoelectric vibrator; and the second connection connects the second interconnect 112a to the top electrode 530 of the piezoelectric vibrator.

Specifically, referring to FIG. 2g, in this embodiment, the bottom electrode 510 with its aforementioned extension is exposed at the surface of the second plastic encapsulation layer 420, and the first interconnect 111a is exposed at the top at the surface of the device wafer 100. Therefore, the device wafer 100 may be bonded to the substrate 300 so that the bottom electrode 510 resides on the front side of the device wafer 100, with a connection being established between its extension and the first interconnect 111a. In this case, the first connection may be considered as being directly provided by the extension of the bottom electrode 510.

With continued reference to FIG. 2g, the second connection may be configured to electrically connect the extension of the top electrode 530 buried within the first plastic encapsulation layer 410 to the second interconnect 112a.

In this embodiment, the second connection may be formed over the substrate 300 after the top electrode 530 and the piezoelectric crystal 520 have been successively formed thereon. Specifically, the formation of the second connection may include the steps detailed below.

At first, a plastic encapsulation layer is formed on the surface of the substrate 300. In this embodiment, this plastic encapsulation layer is made up of the aforementioned first and second plastic encapsulation layers 410, 420.

Next, with reference to FIG. 2g, a through hole is formed in the plastic encapsulation layer, in which the top electrode 530 is exposed, and a conductive material is filled in the through hole, resulting in the formation of a conductive plug (e.g., a third conductive plug 230), the third conductive plug 230 is electrically connected at one end to the top electrode 530, in particular, to the extension of the top electrode 530.

In this embodiment, the through hole extends sequentially through the second plastic encapsulation layer 420 and the first plastic encapsulation layer 410, and the third conductive plug 230 is then formed by filling a conductive material in the through hole. One end of the third conductive plug 230 is electrically connected to the top electrode 530, and the other end thereof is exposed at the surface of the second plastic encapsulation layer 420. As such, an electrical connection can be created between the other end of the third conductive plug 230 and the second interconnect as a result of bonding the substrate 300 to the device wafer 100.

In step S600, with reference to FIG. 2h, the substrate 300 is bonded to the front side of the device wafer 100 such that the piezoelectric vibrator 500 is situated between the device wafer 100 and the substrate 300, with the upper and lower cavities 310, 120 being located on opposing sides of the piezoelectric vibrator 500 to form the crystal resonator. In addition, the top and bottom electrodes 530, 510 of the piezoelectric vibrator 500 are both electrically connected to the control circuit through the first connecting structure.

As discussed above, in this embodiment, the device wafer 100 and the substrate 300 are so bonded that, in the control circuit, the first circuit 111 is electrically connected to the bottom electrode 510 by the first connection (i.e., the extension of the bottom electrode) and the second circuit 112 is electrically connected the top electrode 530 by the second connection (including the third conductive plug 230). In this way, the control circuit can apply an electrical signal to the electrodes sandwiching the piezoelectric crystal 520, which causes the piezoelectric crystal 520 to change its shape and vibrate in the upper and lower cavities 310, 120.

The bonding of the device wafer 100 and the substrate 300 may be accomplished by a method including, for example, applying adhesive layer(s) to the device wafer 100 and/or the substrate 300 and bonding the device wafer 100 and the substrate 300 together by means of the adhesive layer(s). Specifically, an adhesive layer may be applied to the substrate with the piezoelectric crystal formed thereon in such a manner that the surface of the piezoelectric crystal is exposed at a surface of the adhesive layer, and the substrate without the piezoelectric crystal formed thereon may be then bonded to the adhesive layer.

In this embodiment, the piezoelectric vibrator 500 is formed on the substrate 300. Accordingly, the bonding of the device wafer 100 and the substrate 300 may be accomplished by a method including, for example, applying an adhesive layer to the substrate 300 so that the surface of the piezoelectric vibrator 500 is exposed at a surface of the adhesive layer, and then bonding together the substrate 300 and the device wafer 100 by means of the adhesive layer.

Therefore, in this embodiment, the top electrode 530, the piezoelectric crystal 520 and the bottom electrode 510 of the piezoelectric vibrator 500 are all formed on the substrate 300, and the piezoelectric vibrator 500 covers an opening of the upper cavity 310. In addition, the bonding is so performed that the lower cavity 120 is located on the side of the piezoelectric vibrator 500 away from the upper cavity 310 and the crystal resonator is thus formed. In addition, the crystal resonator is electrically connected to the control circuit in the device wafer 100, achieving the integration of the crystal resonator with the control circuit.

In step S700, with reference to FIG. 2i, a semiconductor die 700 is bonded to the back side of the device wafer in such a manner that the semiconductor die 700 is electrically connected to the control circuit by a second connecting structure.

In the semiconductor die 700, for example, a drive circuit for providing an electrical signal may be formed. The electrical signal is applied by the control circuit to the piezoelectric vibrator 500 so as to control shape change of the piezoelectric vibrator 500.

The semiconductor die 700 may be heterogeneous from the device wafer 100. That is, the semiconductor die 700 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

As noted above, the second connecting structure may include conductive plugs and connecting wires for leading connection ports of the control circuit from the front to back side of the device wafer.

The conductive plugs in the second connecting structure may be formed prior to the bonding of the substrate 300, and the formation may involve an etching process performed on the front side of the device wafer and be followed by the formation of the connecting wires. In this case, the method may further include, prior to the bonding of the semiconductor die, thinning the device wafer 100 from the back side thereof until the conductive plugs are exposed and become ready for subsequent electrical connection with the semiconductor die 700 to be bonded.

In this embodiment, the thinning of the device wafer 100 from the back side thereof involves sequential removal of the base layer and the buried oxide layer, which results in the exposure of the top silicon layer and hence of the first and second conductive plugs.

In alternative embodiments, in order to form second connecting structure, the formation of the conductive plugs may involve an etching process performed on the back side of the device wafer. For example, in such embodiments, the formation of the second connecting structure may include the steps detailed below.

At first, prior to the bonding of the substrate 300, connecting wires electrically connecting the control circuit are formed on the front side of the device wafer 100. In this embodiment, the first connecting wire 221b electrically connecting the third interconnect 111b and the second connecting wire 222b electrically connecting the fourth interconnect 112b are formed on the front side of the device wafer 100.

Next, connecting holes, which extend through the device wafer 100 and in which the connecting wires are exposed, are formed by etching the device wafer 100 from the back side thereof. In this embodiment, the connecting holes include a first connecting hole and a second connecting hole, in which the first connecting wire 221b and the second connecting wire 222b are exposed, respectively.

In addition, referring to FIG. 2i, before the first and second connecting holes are formed by etching the device wafer, the device wafer 100 may be thinned from the back side of the device wafer 100. In this way, the first and second connecting holes formed may each have a reduced depth, which facilitates maintaining a desired morphology of the connecting holes.

Subsequently, a conductive material is filled in the connecting holes, resulting in the formation of conductive plugs. One end of each conductive plug is connected to a corresponding one of the connecting wires, and the other end is reserved for subsequent electrical connection with the semiconductor die.

In this embodiment, the first and second conductive plugs 211b, 212b are formed. One end of the first conductive plug 211b is connected to the first connecting wire 221b, and the other end is reserved for subsequent electrical connection with the semiconductor die 700. One end of the second conductive plug 212b is connected to the second connecting wire 222b, and the other end of the second conductive plug 212b is reserved for subsequent electrical connection with the semiconductor die 700.

Subsequently, a plastic encapsulation layer may be further formed over the back side of the device wafer, which encapsulates the semiconductor die.

It is to be noted that, in this embodiment, the bonding of the substrate to the front side of the device wafer precedes the bonding of the semiconductor die to the back side of the device wafer. However, in other embodiments, the bonding of the semiconductor die to the back side of the device wafer may precede the bonding of the substrate to the front side of the device wafer.

Specifically, according to another embodiment, the method for integrating the crystal resonator with the control circuit may include:

bonding the semiconductor die to the back side of the device wafer and forming the second connecting structure which electrically connects the semiconductor die to the control circuit;

forming the lower cavity of the crystal resonator by etching the device wafer from the front side thereof, and

bonding the substrate to the front side of the device wafer and forming the first connecting structure which electrically connects the top and bottom electrodes of the piezoelectric vibrator to the control circuit.

### Embodiment 2

Differing from Embodiment 1, in this embodiment, the top electrode 530, the piezoelectric crystal 520 and the bottom electrode 510 of the piezoelectric vibrator 500 are all formed on the front side of the device wafer 100, and the piezoelectric vibrator 500 covers and closes an opening of the lower cavity 120. In addition, after the crystal resonator is electrically connected to the control circuit in the device wafer 100, a bonding process is performed so that the upper cavity 310 is located on the side of the piezoelectric vibrator 500 away from the lower cavity 120. Forming the crystal resonator in this way also allows integration of the crystal resonator with the control circuit.

Reference can be made to the description of Embodiment 1 for details in the provision of the device wafer containing the control circuit and the formation of the lower cavity in the device wafer, and these are not described here again for the sake of brevity.

In this embodiment, the formation of the piezoelectric vibrator 500 on the device wafer 100 may include the steps detailed below.

At first, the bottom electrode 510 is formed at a predetermined location on the front side of the device wafer 100. In this embodiment, the bottom electrode 510 is positioned around the lower cavity 120.

Then, the piezoelectric crystal 520 is bonded to the bottom electrode 510. In this embodiment, the piezoelectric crystal 520 is so bonded above the lower cavity 120 that it covers and closes the opening of the lower cavity 120, with the peripheral edge portions of the piezoelectric crystal 520 residing on the bottom electrode 510.

Next, the top electrode 530 is formed on the piezoelectric crystal 520.

Of course, in other embodiments, it is also possible to form the top and bottom electrodes respectively on the opposing sides of the piezoelectric crystal and then bond the three as a whole to the front side of the device wafer 100.

In addition, in this embodiment, the bottom electrode 510 and the piezoelectric crystal 520 are sequentially formed over the device wafer 100. At the same time, the first connecting structure may also be formed on the device wafer 100. Specifically, the first connecting structure includes a first connection for electrically connecting the bottom electrode and a second connection for electrically connecting the top electrode.

The bottom electrode 510 has an extension extending beyond the piezoelectric crystal 520, which is able to be electrically connected to the first interconnect. Therefore, the extension of the bottom electrode is considered to make up the first connection that connects the bottom electrode 510 to the control circuit.

The second connection may be formed subsequent to the formation of the piezoelectric crystal 520 and prior to the formation of the top electrode 530.

Specifically, a method for forming the second connection prior to the formation of the top electrode and electrically connecting it to the top electrode may include the following steps:

Step 1: Form a plastic encapsulation layer on the front side of the device wafer 100. In this embodiment, the plastic encapsulation layer covers the front side of the device wafer 100, with the piezoelectric crystal 520 being exposed therefrom.

Step 2: Form a through hole in the plastic encapsulation layer and fill a conductive material in the through hole, thereby resulting in the formation of a conductive plug (e.g., a third conductive plug 230). The resulting third conductive plug 230 is electrically connected to the second interconnect at the bottom and exposed from the plastic encapsulation layer at the top.

Step 3: Form the top electrode 530 on the device wafer 100 in such a manner that the top electrode 530 covers at least part of the piezoelectric crystal 520 and extends therefrom over the top of the third conductive plug and thus come into electrical connection with the conductive plug. That is, the extension of the top electrode 530 extending beyond the piezoelectric crystal is directly electrically connected to the third conductive plug 230.

Alternatively, in step 3, after the top electrode 530 is formed on the piezoelectric crystal 520, an interconnecting wire may be formed on the top electrode 530 so as to extend beyond the top electrode over the top of the third conductive plug. In this way, the top electrode is electrically connected to the third conductive plug via the interconnecting wire. That is, the electrical connection between the top electrode 530 and the third conductive plug is accomplished by the interconnecting wire.

In addition, subsequent to the formation of the piezoelectric vibrator 500 on the device wafer 100 and of the upper cavity 310 in the substrate 300, the substrate 300 may be bonded to the device wafer 100.

Specifically, bonding the substrate 300 to the device wafer 100 may include: applying an adhesive layer to the device wafer 100 in such a manner that the surface of the piezoelectric crystal is exposed from the adhesive layer; and then bonding the device wafer 100 and the substrate 300 together by means of the adhesive layer.

The bonding may be so carried out that the upper cavity in the substrate 300 is located on the side of the piezoelectric crystal 520 away from the lower cavity. The upper cavity may be broader than the piezoelectric crystal so that the piezoelectric crystal can be accommodated within the upper cavity.

In this embodiment, subsequent to the bonding of the substrate to the device wafer, the semiconductor die is bonded to the substrate and electrically connected to the control circuit via the second connecting structure. Reference can be made to the description of Embodiment 1 for details in the formation of the second connecting structure and in the bonding of the semiconductor die, and these are not described here again for the sake of brevity.

### Embodiment 3

Differing from Embodiments 1 and 2 in which the top electrode, piezoelectric crystal and bottom electrode of the piezoelectric vibrator are all formed either on the substrate or on the device wafer, in this embodiment, the top electrode and piezoelectric crystal are formed on the substrate, while the bottom electrode is formed on the device wafer.

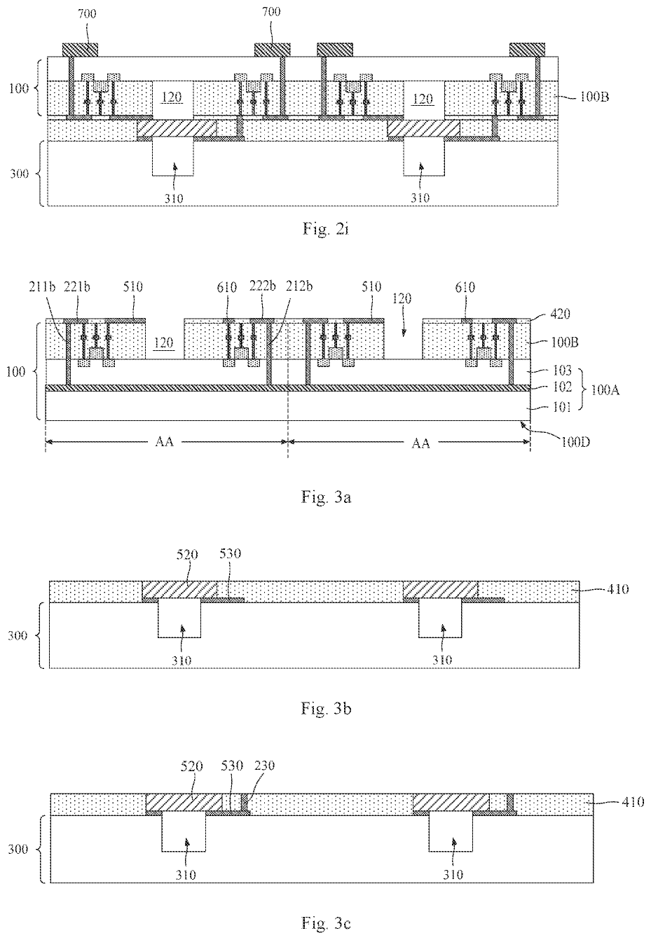

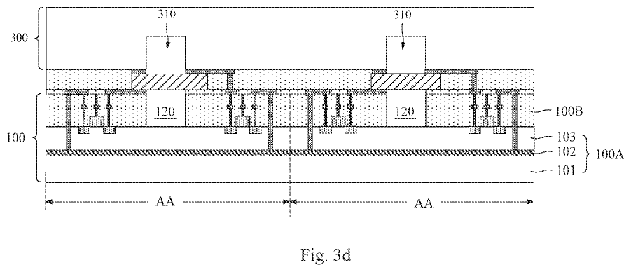

FIGS. 3a to 3d are schematic representations of structures resulting from steps in a method for integrating a crystal resonator with a control circuit according to the third embodiment of the present invention. In the following, steps for forming the crystal resonator will be described in detail with reference to the figures.

Referring now to FIG. 3a, the device wafer 100 containing the control circuit is provided, and the bottom electrode 510 is formed on the front side of the device wafer 100 so that the bottom electrode 510 is electrically connected to the first interconnect.

During the formation of the bottom electrode 510, a rewiring layer 610 may be formed on the device wafer 100, which covers the second interconnect.

In addition, subsequent to the formation of the bottom electrode 510, the method may further include forming a second plastic encapsulation layer 420 on the device wafer 100, which has a surface that is not higher than that of the bottom electrode 510 so that the bottom electrode 510 remains exposed. In this embodiment, the surface of the second plastic encapsulation layer 420 is also not higher than that of the rewiring layer 610 so that the rewiring layer 610 is also exposed. In this way, a subsequent bonding process may be so performed that the bottom electrode 510 is positioned on one side of the piezoelectric crystal, with the rewiring layer 610 being electrically connected to the top electrode located on the other side of the piezoelectric crystal.

The formation of the second plastic encapsulation layer 420 may involve a planarization process for making the surface of the second plastic encapsulation layer 420 flush with that of the bottom electrode 510. In this way, a significant improved surface flatness can be provided to the device wafer 100, which is favorable to the subsequent bonding process.

With continued reference to FIG. 3a, in this embodiment, subsequent to the successive formation of the bottom electrode 510 and the second plastic encapsulation layer 420, the lower cavity 120 can be formed by successively etching through the second plastic encapsulation layer 420 and the dielectric layer 100B so that the bottom electrode 510 is positioned around the lower cavity 120.

With similarity to Embodiment 1, in this embodiment, in order to form the second connecting structure, the device wafer is etched from the front side thereof in order to form conductive plugs of the second connecting structure (including the first and second conductive plugs 211b, 212b), and connecting wires of the second connecting structure (including the first and second connecting wires 221b, 222b) are then formed on the front side of the device wafer.

With continued reference to FIG. 3b, the substrate 300 is provided and the top electrode 530 and the piezoelectric crystal 520 are successively formed on the substrate 300 above the upper cavity. The top electrode may be formed using a vapor deposition process or a thin-film deposition process, followed by bonding the piezoelectric crystal to the top electrode.

Specifically, the top electrode 530 is positioned around the upper cavity 310 and the top electrode 530 will be electrically connected to the rewiring layer 610 on the device wafer 100 and hence to the second interconnect 112a in the second circuit 112 in a subsequent process. Moreover, the piezoelectric crystal 520 may be so positioned that a central portion thereof interfaces with the upper cavity 310 in the substrate 300, with the peripheral edge portions of the piezoelectric crystal 520 residing on top edges of the top electrode 530. Moreover, an extension of the top electrode 530 may extend beyond the piezoelectric crystal 520 thereunder.

With continued reference to FIG. 3b, in this embodiment, subsequent to the formation of the piezoelectric crystal 520, the method may further include forming a first plastic encapsulation layer 410 on the substrate 300, the first plastic encapsulation layer 410 covers the substrate 300 and the extension of the top electrode 530. The first plastic encapsulation layer 410 may have a surface not higher than that of the piezoelectric crystal 520 so that the piezoelectric crystal 520 is exposed therefrom.

Similarly, in this embodiment, the formation of the first plastic encapsulation layer 410 may also involve a planarization process for making the surface of the first plastic encapsulation layer 410 flush with that of the piezoelectric crystal 520. In this way, the substrate 300 may be provided with a flatter surface, which is favorable to the subsequent bonding process.

Subsequently, referring to FIG. 3c, a conductive plug of the first connecting structure is formed on the device wafer 100 or in the substrate 300 so that after the substrate 300 is bonded to the device wafer 100, the top electrode 530 can be electrically connected to the second interconnect via the first connecting structure. The formation of the conductive plug of the first connecting structure may include the steps detailed below.

At first, a plastic encapsulation layer is formed on the surface of the substrate 100. In this embodiment, the plastic encapsulation layer is made up of the aforementioned first plastic encapsulation layer 410.

Next, the plastic encapsulation layer is etched so that a through hole is formed therein. In this embodiment, the first plastic encapsulation layer 410 is etched, and the extension of the top electrode 530 is exposed in the resulting through hole. A conductive material is then filled in the through hole, resulting in the formation of the conductive plug (e.g., the aforementioned third conductive plug 230), which is exposed at the top at the surface of the first plastic encapsulation layer 410. Specifically, the third conductive plug 230 is connected to the extension of the top electrode 530. As a result, the top electrode 530 is electrically connected to the second interconnect via the third conductive plug 230 and the rewiring layer 610.

Afterward, referring to FIG. 3d, the substrate 300 is bonded to the front side of the device wafer so that the lower cavity 120 is positioned on the side of the piezoelectric crystal 520 away from the upper cavity 310. Accordingly, the bottom electrode 510 on the device wafer 100 is located on the side of the piezoelectric crystal 520 away from the top electrode 530.

In this embodiment, the bonding of the substrate 300 to the device wafer 100 may include: applying an adhesive layer to the substrate 300 in such a manner that the surface of the piezoelectric crystal 520 is exposed from the adhesive layer; and then bonding the device wafer and the substrate together by means of the adhesive layer.

Specifically, the bonding of the substrate 300 to the device wafer 100 may bring the rewiring layer 610 on the device wafer 100 that is connected to the second conductive plug into electrical contact with the third conductive plug 230 on the substrate 300 that is connected to the top electrode 530, resulting in electrical connection of the top electrode 530 to the control circuit.

In a subsequent process, the second connecting structure is formed and the semiconductor die is bonded. Reference can be made to the description of Embodiment 1 for more details in this regard, and a repeated description thereof will be omitted here for the sake of brevity.

A structure for integrating a crystal resonator with a control circuit corresponding to the above method will be described below with combined reference to FIGS. 2a to 2i and 3d. The crystal resonator includes:

a device wafer 100, in which the control circuit and a lower cavity 120 are formed, the lower cavity 120 exposed at a front side of the device wafer 100, the control circuit including interconnects, at least some of which extend to the front side of the device wafer 100;

a substrate 300, which is bonded to the device wafer 100 from the front side thereof, and an upper cavity 310 is formed in the substrate 300, the upper cavity 310 having an opening facing the device wafer 100, i.e., in opposition to an opening of the lower cavity 120;

a piezoelectric vibrator 500 including a bottom electrode 510, a piezoelectric crystal 520 and a top electrode 530, the piezoelectric vibrator 500 arranged between the device wafer 100 and the substrate 300 so that the lower and upper cavities 120, 310 are on opposing sides of the piezoelectric vibrator 500;

a first connecting structure configured to electrically connect the top and bottom electrodes 530, 510 of the piezoelectric vibrator 500 to the control circuit;

a semiconductor die 700 bonded to a back side of the device wafer 100, wherein in the semiconductor die 700, there is formed, for example, a drive circuit for producing an electrical signal to be transmitted to the piezoelectric vibrator 500 via the control circuit 100; and

a second connecting structure configured to electrically connect the semiconductor die 700 to the control circuit.

The semiconductor die 700 may be heterogeneous from the device wafer 100. That is, the semiconductor die 700 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.

The lower cavity 120 in the device wafer 100 and the upper cavity 310 in the substrate 300 may be formed using planar fabrication processes, and the device wafer 100 and the substrate 300 may be bonded together so that the upper and lower cavities 120, 310 are positioned in opposition to each other and respectively on opposing sides of the piezoelectric vibrator 500. In this way, the piezoelectric vibrator 500 and the control circuit can be integrated on the same device wafer so that the control circuit can cause the piezoelectric vibrator 500 to oscillate within the upper and lower cavities 310, 120. In addition, the semiconductor die bonded to the device wafer 100 can enhance performance of the crystal resonator by on-chip modulation under the control of the control circuit 110 for correcting raw deviations of the crystal resonator such as temperature and frequency drifts. Therefore, in addition to an enhanced degree of integration, the crystal resonator of the present invention fabricated using the semiconductor processes are more compact in size and thus less power-consuming.

With continued reference to FIG. 2a, the control circuit may include a first circuit 111 and a second circuit 112, the first circuit 111 and the second circuit 112 are electrically connected to the top and bottom electrodes of the piezoelectric vibrator 500, respectively.

Specifically, the first circuit 111 may include a first transistor, a first interconnect 111a and a third interconnect 111b. The first transistor may be buried within the device wafer 100, and the first interconnect 111a and the third interconnect 111b may be both connected to the first transistor and extend to the front side of the device wafer 100. The first interconnect 111a may be electrically connected to the bottom electrode 510 and the third interconnect 111b to the semiconductor die.

Similarly, the second circuit 112 may include a second transistor, a second interconnect 112a and a fourth interconnect 112b. The second transistor may be buried within the device wafer 100, and the second interconnect 112a and the fourth interconnect 112b may be both connected to the second transistor and extend to the front side of the device wafer 100. The second interconnect 112a may be electrically connected to the top electrode 530 and the fourth interconnect 112b to the semiconductor die.

In addition, the first connecting structure may include a first connection and a second connection. The first connection may be connected to the first interconnect 111a and the bottom electrode 510 of the piezoelectric vibrator. The second connection may be connected to the second interconnect 112a and the top electrode 530 of the piezoelectric vibrator.

In this embodiment, the bottom electrode 510 is situated on the front side of the device wafer 100 around the lower cavity 120 and has an extension extending laterally beyond the piezoelectric crystal 520. Additionally, the extension of the bottom electrode 510 covers the first interconnect 111a in the first circuit 111 so as to bring the bottom electrode 210 into electrical connection with the first interconnect 111a in the first circuit 111. Therefore, it can be considered that the extension of the bottom electrode makes up the first connection.

Further, the top electrode 530 is formed on the piezoelectric crystal 520 and is electrically connected to the second interconnect 112a in the second circuit 112 via the second connection.

Specifically, the second connection may include a conductive plug (e.g., the aforementioned third conductive plug 230), the third conductive plug 230 is electrically connected to the top electrode 530 at one end and to the second interconnect 112a at the other end. For example, the top electrode 530 may extend from the piezoelectric crystal over one end of the third conductive plug.

Further, a plastic encapsulation layer may be arranged between the device wafer 100 and the substrate 300 such as to cover side surfaces of the piezoelectric crystal 520 and both the extensions of the top and bottom electrodes. The third conductive plug 230 of the second connection may penetrate through the plastic encapsulation layer so as to be electrically connected to the extension of the top electrode at one end and to the second conductive plug at the other end.

Of course, in other embodiments, the second connection may further include an interconnecting wire, which covers the top electrode 530 at one end and covers at least part of the top of the third conductive plug at the other end. In this way, the top electrode 530 is electrically connected to the control circuit via both the interconnecting wire and the third conductive plug.

In addition, the second connecting structure that connects the semiconductor die 700 to the control circuit may include conductive plugs and connecting wires. Each of the conductive plugs in the second connecting structure may extend through the device wafer 100 so as to be located at the front side of the device wafer 100 at one end and to be located at the back side of the device wafer 100 and electrically connected to the semiconductor die 700 at the other end. The connecting wires may be formed on the front side of the device wafer 100 and connect the respective conductive plugs to the control circuit.

Thus, the conductive plugs and connecting wires lead connection ports of the control circuit, to which the semiconductor die is to be electrically connected, from the front to back side of the device wafer. As a result, the semiconductor die is allowed to be arranged on the back side of the device wafer and brought into electrical connection to the control circuit there.

In this embodiment, the conductive plugs of the second connecting structure include a first conductive plug 211b and a second conductive plug 212b, and the connecting wires of the second connecting structure include a first connecting wire 221b and a second connecting wire 222b. The first connecting wire 221b connects the first conductive plug 211b to the third interconnect 111b, and the second connecting wire 222b connects the second conductive plug 212b to the fourth interconnect 112b.

With continued reference to FIG. 2a, in this embodiment, the device wafer 100 includes a substrate wafer 100A and a dielectric layer 100B. The first and second transistors may be both formed on the substrate wafer 100A, and the dielectric layer 100B may reside on the substrate wafer 100A and thus cover both the first and second transistors. Each of the third interconnect 111b, the first interconnect 111a, the fourth interconnect 112b and the second interconnect 112a may be formed in the dielectric layer 100B such as to extend to the surface of the dielectric layer 100B away from the substrate wafer 100A.

The structure may further include a plastic encapsulation layer, which is formed over the back side of the device wafer so as to cover the semiconductor die 700.

In summary, in the method of the present invention, integration of the crystal resonator with the control circuit on a single device wafer is accomplished by bonding the substrate containing the upper cavity to the device wafer containing the lower cavity so that the piezoelectric vibrator is sandwiched between the device wafer and the substrate, with the lower and upper cavities being positioned on the opposing sides of the piezoelectric vibrator. Additionally, for example, the semiconductor die containing the drive circuit may be further bonded to the back side of the device wafer. In other words, the semiconductor die, control circuit and crystal resonator may be integrated on the same semiconductor substrate. This is favorable to on-chip modulation for correcting raw deviations of the crystal resonator such as temperature and frequency drifts. Compared with traditional crystal resonators (e.g., surface-mount ones), in addition to being able to integrate with other semiconductor components more easily with a higher degree of integration, the crystal resonator of the present invention that is fabricated using planar fabrication processes is more compact in size and hence less power-consuming.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer having the control circuit formed therein;
forming a lower cavity of the crystal resonator in the device wafer by etching the device wafer from a front side thereof;
providing a substrate and etching the substrate so that an upper cavity of the crystal resonator is formed therein, wherein the upper cavity is formed in opposition to the lower cavity;
forming a piezoelectric vibrator comprising a top electrode, a piezoelectric crystal and a bottom electrode, which are formed either on the front side of the device wafer or on the substrate;
forming a first connecting structure on the device wafer or on the substrate;
bonding the substrate to the front side of the device wafer such that the piezoelectric vibrator is located between the device wafer and the substrate, with the upper and lower cavities being located on two sides of the piezoelectric vibrator, and with the first connecting structure electrically connecting both the top and bottom electrodes of the piezoelectric vibrator to the control circuit; and
bonding a semiconductor die to a back side of the device wafer and forming a second connecting structure electrically connecting the semiconductor die to the control circuit.

2. The method for integrating a crystal resonator with a control circuit of claim 1, wherein the device wafer comprises a substrate wafer and a dielectric layer on the substrate wafer, wherein the lower cavity is formed in the dielectric layer, wherein the substrate wafer is a silicon-on-insulator substrate comprising a base layer, a buried oxide layer and a top silicon layer stacked in sequence from the back side to the front side, and wherein the lower cavity further extends into the buried oxide layer from the dielectric layer.

3. (canceled)

4. The method for integrating a crystal resonator with a control circuit of claim 1, wherein the piezoelectric vibrator is formed on the front side of the device wafer or on the substrate, or wherein the bottom electrode of the piezoelectric vibrator is formed on the front side of the device wafer, and the top electrode and the piezoelectric crystal of the piezoelectric vibrator are sequentially formed on the substrate, or wherein the bottom electrode and the piezoelectric crystal of the piezoelectric vibrator are sequentially formed on the front side of the device wafer and the top electrode of the piezoelectric vibrator is formed on the substrate.

5. The method for integrating a crystal resonator with a control circuit of claim 4, wherein the formation of the piezoelectric vibrator on the front side of the device wafer comprises:
forming the bottom electrode at a predetermined location on the front side of the device wafer;
bonding the piezoelectric crystal to the bottom electrode; and
forming the top electrode on the piezoelectric crystal, or comprises:
forming the top and bottom electrodes of the piezoelectric vibrator on the piezoelectric crystal; and bonding the top and bottom electrodes and the piezoelectric crystal as a whole to the front side of the device wafer, and/or
wherein the formation of the piezoelectric vibrator on the substrate comprises:
forming the top electrode at a predetermined location on a surface of the substrate;
bonding the piezoelectric crystal to the top electrode; and
forming the bottom electrode on the piezoelectric crystal, or comprises:
forming the top and bottom electrodes of the piezoelectric vibrator on the piezoelectric crystal; and bonding the top and bottom electrodes and the piezoelectric crystal as a whole to the substrate.

6. (canceled)

7. The method for integrating a crystal resonator with a control circuit of claim 5, wherein the formation of the bottom electrode comprises a vapor deposition process or a thin-film deposition process, and wherein the formation of the top electrode comprises a vapor deposition process or a thin-film deposition process.

8. The method for integrating a crystal resonator with a control circuit of claim 4, wherein the top electrode is formed on the substrate and the bottom electrode is formed on the front side of the device wafer, wherein each of the top and bottom electrodes is formed using a vapor deposition process or a thin-film deposition process, and wherein the piezoelectric crystal is bonded to the top electrode or the bottom electrode.

9. The method for integrating a crystal resonator with a control circuit of claim 1, wherein the control circuit comprises a first interconnect and a second interconnect and the first connecting structure comprises a first connection and a second connection,
the first connection connecting the first interconnect to the bottom electrode of the piezoelectric vibrator, the second connection connecting the second interconnect to the top electrode of the piezoelectric vibrator.

10. The method for integrating a crystal resonator with a control circuit of claim 9, wherein the bottom electrode is formed on the front side of the device wafer and has an extension extending beyond the piezoelectric crystal thereunder to come into electrical connection with the first interconnect, the extension of the bottom electrode extending beyond the piezoelectric crystal forming the first connection.

11. The method for integrating a crystal resonator with a control circuit of claim 9, wherein the first connection is formed on the device wafer and electrically connected to the first interconnect prior to the formation of the bottom electrode on the device wafer and is electrically connected to the bottom electrode subsequent to the formation of the bottom electrode on the device wafer, and wherein the first connection comprises a rewiring layer connected to the first interconnect, and wherein the rewiring layer is electrically connected to the bottom electrode subsequent to the formation of the bottom electrode on the device wafer.

12. (canceled)

13. The method for integrating a crystal resonator with a control circuit of claim 9, wherein the piezoelectric crystal is formed on the front side of the device wafer, and wherein the second connection is formed on the device wafer and electrically connected to the second interconnect prior to the presence of the top electrode on the device wafer and is electrically connected to the top electrode subsequent to the presence of the top electrode on the device wafer, and
wherein the formation of the second connection comprises:
forming a plastic encapsulation layer on the front side of the device wafer;
forming a through hole in the plastic encapsulation layer and filling a conductive material in the through hole, thus resulting in the formation of a conductive plug which has a bottom electrically connected to the second interconnect and has a top exposed from the plastic encapsulation layer; and
forming the top electrode on the device wafer so that the top electrode has an extension, which extends beyond the piezoelectric crystal over the top of the conductive plug, thus bringing the top electrode into electrical connection with the conductive plug, or forming the top electrode on the device wafer and an interconnecting wire on the plastic encapsulation layer, which covers the top electrode at one end and covers the conductive plug on the other end.

14. (canceled)

15. The method for integrating a crystal resonator with a control circuit of claim 9, wherein the top electrode and the piezoelectric crystal are sequentially formed on the substrate, and wherein the second connection is formed on the substrate and electrically connected to the top electrode prior to the bonding of the substrate to the device wafer and is electrically connected to the second interconnect subsequent to the bonding of the substrate to the device wafer, and
wherein the formation of the second connection comprises:
forming a plastic encapsulation layer on a surface of the substrate;
forming a through hole in the plastic encapsulation layer, in which the top electrode is exposed, and filling a conductive material in the through hole, thus resulting in the formation of a conductive plug electrically connected at one end to the top electrode; and
electrically connecting the other end of the conductive plug to the second interconnect as a result of the bonding of the substrate to the device wafer.

16. (canceled)

17. The method for integrating a crystal resonator with a control circuit of claim 1, wherein the formation of the second connecting structure comprises:
forming connecting holes in the device wafer by etching the device wafer from the front side thereof;
forming conductive plugs by filling a conductive material in the connecting holes;
forming connecting wires on the front side of the device wafer, which connect the respective conductive plugs to the control circuit; and
thinning the device wafer from the back side thereof until the conductive plugs are exposed for electrical connection with the semiconductor die, or wherein
the formation of the second connecting structure comprises:
forming connecting wires on the front side of the device wafer, which are electrically connected to the control circuit;
etching the device wafer from the back side thereof so that connecting holes are formed therein, which extend through the device wafer, and in which the respective connecting wires are exposed; and
filling a conductive material in the connecting holes so that conductive plugs are formed, which are connected to the respective connecting wires at one end and for electrical connection with the semiconductor die at the other end.

18. (canceled)

19. The method for integrating a crystal resonator with a control circuit of claim 1, wherein the bonding of the substrate to the device wafer comprises:
applying an adhesive layer to the device wafer and/or the substrate and bonding the device wafer and the substrate together by means of the adhesive layer.

20. The method for integrating a crystal resonator with a control circuit of claim 19, wherein the top electrode and the piezoelectric crystal of the piezoelectric vibrator are sequentially formed on the substrate, and wherein
the bonding comprising:
applying an adhesive layer to the substrate so that a surface of the piezoelectric crystal is exposed from the adhesive layer; and
bonding the device wafer and the substrate together by means of the adhesive layer, or
wherein the bottom electrode and the piezoelectric crystal of the piezoelectric vibrator are sequentially formed on the device wafer, and wherein
the bonding comprising:
applying an adhesive layer to the device wafer so that a surface of the piezoelectric crystal is exposed from the adhesive layer; and
bonding the device wafer and the substrate together by means of the adhesive layer.

21. (canceled)

22. The method for integrating a crystal resonator with a control circuit of claim 1, wherein the bonding of the substrate to the front side of the device wafer precedes the bonding of the semiconductor die to the back side of the device wafer, or wherein
the bonding of the semiconductor die to the back side of the device wafer precedes the bonding of substrate to the front side of the device wafer.

23. A structure for integrating a crystal resonator with a control circuit, comprising:
a device wafer in which the control circuit and a lower cavity are formed, the lower cavity exposed from a front side of the device wafer;
a substrate, which is bonded to the device wafer from the front side thereof, and in which an upper cavity is formed, the upper cavity having an opening arranged in opposition to an opening of the lower cavity;
a piezoelectric vibrator comprising a top electrode, a piezoelectric crystal and a bottom electrode, the piezoelectric vibrator arranged between the device wafer and the substrate so that the lower and upper cavities are on two sides of the piezoelectric vibrator;
a first connecting structure configured to electrically connect the top and bottom electrodes of the piezoelectric vibrator to the control circuit;
a semiconductor die bonded to a back side of the device wafer; and
a second connecting structure configured to electrically connect the semiconductor die to the control circuit.

24. The structure for integrating a crystal resonator with a control circuit of claim 23, wherein the device wafer comprises a substrate wafer and a dielectric layer on the substrate wafer, wherein the lower cavity is formed in the dielectric layer, wherein the substrate wafer is a silicon-on-insulator substrate comprising a base layer, a buried oxide layer and a top silicon layer stacked in sequence from the back side to the front side, and wherein the lower cavity further extends into the buried oxide layer from the dielectric layer.

25. (canceled)

26. The structure for integrating a crystal resonator with a control circuit of claim 23, wherein the control circuit comprises a first interconnect and a second interconnect and the first connecting structure comprises a first connection and a second connection,
the first connection connected to both the first interconnect and the bottom electrode of the piezoelectric vibrator, the second connection connected to both the second interconnect and the top electrode of the piezoelectric vibrator.

27. The structure for integrating a crystal resonator with a control circuit of claim 26, wherein the bottom electrode is formed on the front side of the device wafer and has an extension extending beyond the piezoelectric crystal to come into electrical connection with the first interconnect, the extension of the bottom electrode extending beyond the piezoelectric crystal forming the first connection.

28. The structure for integrating a crystal resonator with a control circuit of claim 26, wherein the second connection comprises a conductive plug which is electrically connected to the top electrode at one end and to the second interconnect at the other end, or
wherein the second connection comprises:
a conductive plug, which is formed on the front side of the device wafer and has a bottom electrically connected to the second interconnect; and
an interconnecting wire covering the top electrode at one end and covering a top of the conductive plug at the other end, or wherein
the second connecting structure comprises:
conductive plugs, which extend through the device wafer so that the conductive plugs are each located at the front side of the device wafer at one end and are located at the back side of the device wafer and electrically connected to the semiconductor die at the other end; and
connecting wires formed on the front side of the device wafer, the connecting wires connecting the respective conductive plug to the control circuit.

29-30. (canceled)
